(19) United States
(12) Patent Application Publication
(10) Pub. No.: US 2025/0286528 A1
(43) Pub. Date: Sep. 11, 2025

(54) NOISE FILTER AND POWER CONVERSION APPARATUS

(71) Applicant: Panasonic Automotive Systems Co., Ltd., Kanagawa (JP)

(72) Inventors: Susumu NAKAMURA, Kanagawa (JP); Shuzo ISODA, Kanagawa (JP); Hirohide OKAHARA, Kanagawa (JP); Ryo ISHIKAWA, Kanagawa (JP); Kouichi IGASHIRA, Kanagawa (JP)

(21) Appl. No.: 19/067,402

(22) Filed: Feb. 28, 2025

(30) Foreign Application Priority Data
Mar. 8, 2024 (JP) 2024-035714
Apr. 23, 2024 (JP) 2024-069532

(51) Int. Cl. H03H 7/01; H02M 1/44; H02M 7/00; H03H 1/00

(52) U.S. Cl. CPC H03H 7/0115; H02M 1/44; H02M 7/003; H03H 1/00; H03H 2001/005

(57) ABSTRACT

A noise filter includes a cooling plate, a coil of a type of a plurality of wires of a plurality of phases, a plurality of wiring lines, and a plurality of capacitors. The cooling plate has thermal conductivity, and is formed in a flat plate shape. The coil is formed in an annular shape, and is fixed to a first principal face of the cooling plate. The plurality of wiring lines are electrically connected to leads that extend from windings of the plurality of phases. The plurality of capacitors are electrically connected to the plurality of wiring lines. The coil is thermally connected to the first principal face of the cooling plate, and an axis direction of the annular shape extends along the first principal face, in a state where the coil is fixed to the first principal face.

### CROSS-REFERENCE TO RELATED APPLICATIONS

This application is based upon and claims the benefit of priority from Japanese Patent Application No. 2024-035714, filed Mar. 8, 2024 and Japanese Patent Application No. 2024-069532, filed Apr. 23, 2024, the entire contents of which are incorporated herein by reference.

### FIELD

The present disclosure relates to a noise filter and a power conversion apparatus.

### BACKGROUND

Conventionally, a power conversion apparatus, such as an on-board charger, that is operable according to an input of an alternating current (AC) voltage from, for example, each of a three-phase AC power supply and a single-phase AC power supply is known.

For example, JP 2021-145448 A discloses a technique relating to a switching power supply apparatus that includes a plurality of power conversion circuits that corresponds to respective phases of a plural-phase AC power supply serving as an external power supply, and is provided with a noise filter that is configured by using a coil and a capacitor in order to prevent noise from entering from the external power supply and prevent noise from flowing out to the external power supply.

Under the circumstances, it has been requested that power conversion apparatuses, such as chargers, that are mounted in electric vehicles or the like be reduced in size due to, for example, limitations on a mounting space. However, in a case where noise filters of the power conversion apparatuses are mounted with a plural-phase plural-wire type coil, there is a need for a space for drawing around a wiring line from each of a plurality of windings, and there have been limitations on a reduction in size. Therefore, the noise filters including the plural-phase plural-wire type coil have room for improvements from the viewpoint of, for example, a reduction in size.

A problem to be solved by the present disclosure is to achieve a reduction in size of a noise filter including the plural-phase plural-wire type coil.

### SUMMARY

A noise filter according to the present disclosure includes a cooling plate, a coil of a type of a plurality of wires of a plurality of phases, a plurality of wiring lines, and a plurality of capacitors. The cooling plate has thermal conductivity, and is formed in a flat plate shape. The coil is formed in an annular shape, and is fixed to a first principal face of the cooling plate. The plurality of wiring lines are electrically connected to leads that extend from windings of the plurality of phases. The plurality of capacitors are electrically connected to the plurality of wiring lines. The coil is thermally connected to the first principal face of the cooling plate, and an axis direction of the annular shape extends along the first principal face, in a state where the coil is fixed to the first principal face.

### BRIEF DESCRIPTION OF THE DRAWINGS

FIG. 1 is a perspective view illustrating an example of a configuration of a noise filter that is mounted in a power conversion apparatus according to an embodiment;

FIG. 2 is a top view illustrating an example of a configuration of the noise filter of FIG. 1;

FIG. 3 is a sectional view illustrating an example of the configuration of the noise filter of FIG. 1; and

FIG. 4 is a diagram schematically illustrating an example of a configuration of a noise filter in a comparative example.

### DETAILED DESCRIPTION

Embodiments of a noise filter, a power conversion apparatus, and a vehicle according to the present disclosure are described below with reference to the drawings.

Note that in the description of the present disclosure, a component that has the same or roughly the same function as a function of a component described with reference to an already described drawing is denoted by the same reference sign, and description is appropriately omitted in some cases. Furthermore, even in a case where the same or roughly the same portion is indicated, the portion is indicated to have dimensions or a ratio that change(s) depending on the drawings in some cases. Furthermore, for example, from the viewpoint of securing visibility of the drawings, in the description of each of the drawings, only principal components are denoted by reference signs, and even a component that has the same or roughly the same function as a function of a component described with reference to an already described drawing is not denoted by a reference sign in some cases.

Note that in the description of the present disclosure, components having the same or roughly the same function are described to be distinguished from each other by adding alphanumeric characters at the end of a reference sign in some cases. Alternatively, in a case where a plurality of components having the same or roughly the same function is not distinguished from each other, the plurality of components is collectively described by omitting the alphanumeric characters added at the end of the reference sign in some cases.

Note that in the description of the present disclosure, an expression such as “orthogonal”, “horizontal”, “vertical”, “parallel”, “same”, “match”, or “same position” is not strictly limited to the case of “orthogonal”, “horizontal”, “vertical”, “parallel”, “same”, “match”, or “same position”, and includes a case that can be regarded as “orthogonal”, “horizontal”, “vertical”, “parallel”, “same”, “match”, or “same position”.

A power conversion apparatus according to the present disclosure may be mounted in a vehicle, for example, as an on-board charger. For example, the power conversion apparatus may be an on-board charger that converts AC power supplied from an external single-phase or three-phase AC power supply into direct current (DC) power, and supplies the converted DC power to a load that is mounted in the vehicle. This load may be, for example, a battery, an inverter, a motor, or various pieces of electric equipment.

Note that, as the vehicle, various moving bodies, such as cars, freight cars, buses, motorcycles, or electric scooters, that can be driven or can drive an accessory (electric equipment) of the vehicle by using power from the battery can be appropriately used. Conceivable examples of this electric equipment include navigation devices, audio equipment, air-conditioners, power windows, defoggers, electronic control units (ECUs), global positioning system (GPS) modules, on-board cameras, and the like. Furthermore, it is sufficient if the battery of the vehicle can store power for driving a drive motor (a traction motor), electric equipment, or the like that is mounted in the vehicle, and for example, an arbitrary battery, such as a lithium-ion battery, a nickel-hydrogen battery, or a solid-state battery, can be appropriately used. Note that the power conversion apparatus according to the present disclosure is not limited to the vehicle, and may be provided in, for example, airplanes, game facilities, or uninterruptible power supply devices.

The power conversion apparatus according to the present disclosure is provided with a noise filter that prevents noise from entering from an external AC power supply to the power conversion apparatus, and prevents noise from flowing out from the power conversion apparatus to the AC power supply (removes noise). Furthermore, for example, in a post-stage of the noise filter, a power conversion circuit that converts, into DC power, AC power that has been supplied from an external single-phase or three-phase AC power supply via the noise filter, and outputs the converted DC power, is provided. This power conversion circuit is provided with, for example, a power factor correction (PFC) circuit that rectifies and smooths an AC voltage from the external AC power supply after causing the noise filter to remove noise, and generates a DC voltage. Furthermore, for example, in a post-stage of the PFC circuit in the power conversion circuit, a DC-DC conversion circuit that again converts the DC voltage generated by the PFC circuit into the AC voltage, and then rectifies and smooths the AC voltage to generate a DC voltage having an arbitrarily set voltage, is provided.

In the power conversion apparatus according to the present disclosure, each of the noise filter and the power conversion circuit is disposed on a cooling surface of a housing of the power conversion apparatus. As an example, each of the noise filter and the power conversion circuit is disposed on the cooling surface of the housing of the power conversion apparatus, for example, in a state where some or all of the components (electronic components) of the noise filter or the power conversion circuit have been integrally assembled (modularized). These modularized components are detachably fixed to the cooling surface of the housing of the power conversion apparatus by using a fixing member (not illustrated) such as a screw.

Each of the noise filter and the power conversion circuit is thermally connected to the cooling surface of the housing of the power conversion apparatus. Here, to be “thermally connected” means to be “configured in a heat exchangeable manner”. Note that heat transport between each of the noise filter and the power conversion apparatus and the housing of the power conversion apparatus is achieved by using, for example, heat conduction, but heat transport may be performed in another form in addition to or instead of heat conduction. Furthermore, this heat transport may be performed via another component.

The housing of the power conversion apparatus according to the present disclosure is formed of a metal material such as die casting. The housing of the power conversion apparatus forms a liquid cooling type cooling mechanism that uses, as working fluid, coolant such as antifreezing fluid. For example, inside the housing of the power conversion apparatus, a flow passage of the coolant that extends in a direction along the cooling surface (for example, a horizontal direction) is formed. Stated another way, inside the housing of the power conversion apparatus, a flow passage that runs in one plane (the cooling surface) is formed.

Note that the flow passage of the coolant that is formed in the housing of the power conversion apparatus according to the present disclosure may branch at least in two directions in one plane along the cooling surface. On the other hand, the flow passage does not branch in a direction that is orthogonal to the cooling surface. In other words, in the housing of the power conversion apparatus, in a case where there is a crossing portion where at least flow passages of two directions cross each other, each of the flow passages extends from the crossing portion in a direction that is parallel to the cooling surface, but does not extend in the direction that is orthogonal to the cooling surface. As described above, in the power conversion apparatus according to the present disclosure, a flow passage that only runs in one plane forms a mechanism that cools down the entirety of a system.

### Embodiments

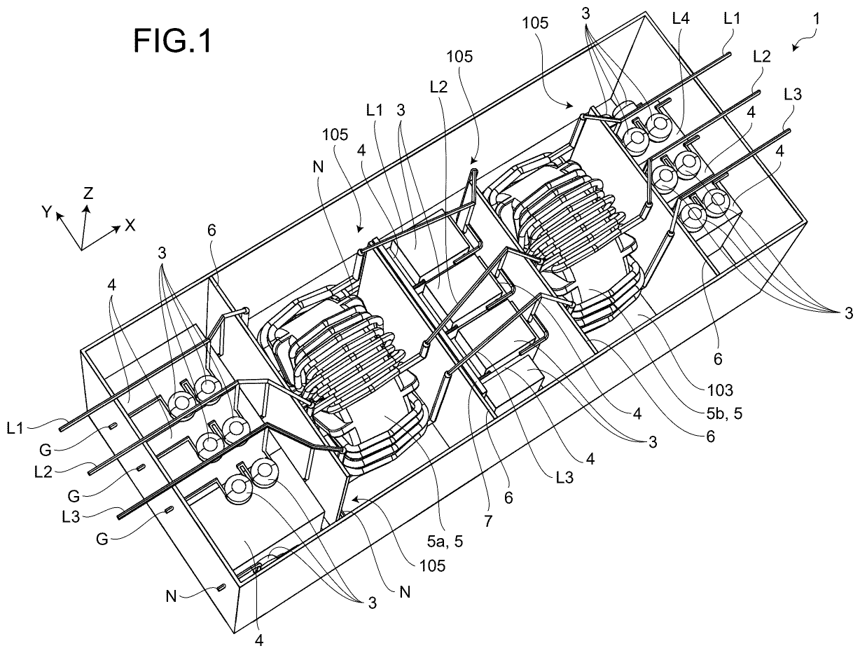

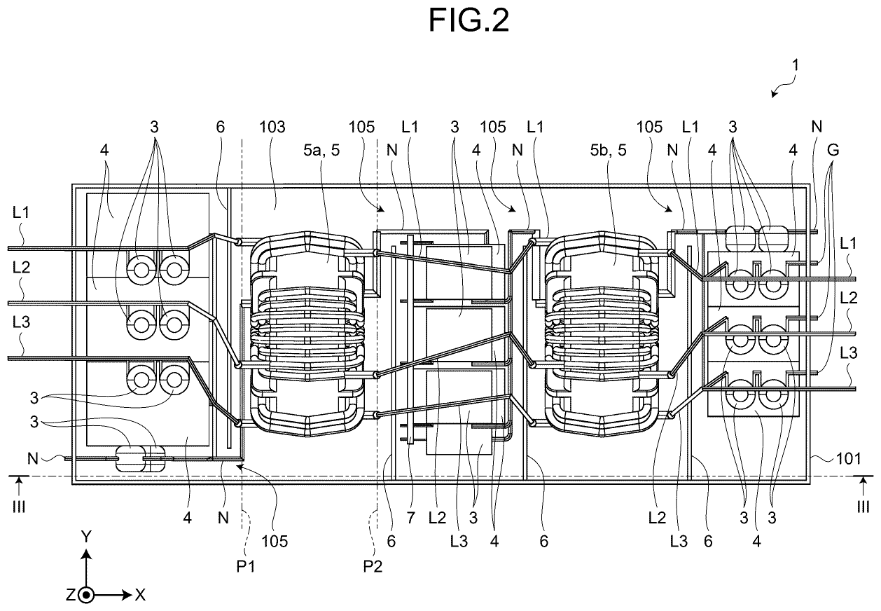

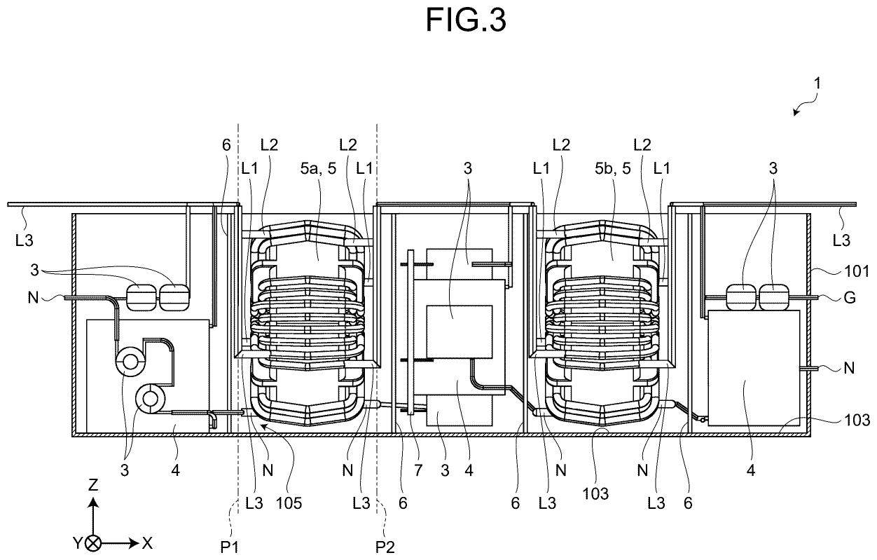

FIG. 1 is a perspective view illustrating an example of a configuration of a noise filter 1 that is mounted in a power conversion apparatus according to an embodiment. FIG. 2 is a top view illustrating an example of a configuration of the noise filter 1 of FIG. 1. FIG. 3 is a sectional view illustrating an example of the configuration of the noise filter 1 of FIG. 1. FIG. 3 illustrates a cross section of plane III-III (a Z-X plane) of FIG. 2 when viewed from a lower side of a sheet (a −Y side).

As illustrated in FIGS. 1 to 3, the noise filter 1 includes a housing 101 that is formed in a box shape, and a cooling plate 103. Note that FIGS. 1 to 3 do not illustrate an upper face (an X-Y plane on a +Z side) of the housing 101 of the noise filter 1. The housing 101 of the noise filter 1 is formed by using a metal material having thermal conductivity, such as die casting or aluminum.

As illustrated in FIGS. 1 to 3, the cooling plate 103 of the noise filter 1 is formed in a flat plate shape, and forms a lower face (an X-Y plane on a −Z side) of the housing 101. The cooling plate 103 has thermal conductivity at least in a thickness direction (a Z direction). It is preferable that the cooling plate 103 further have thermal conductivity in a direction along a principal face (an X-Y plane), and have a function as a heat diffusion plate (heat capacity).

As illustrated in FIGS. 1 to 3, on a first

principal face serving as the principal face (the X-Y plane) on an upper face side (the +Z side) of the cooling plate 103, respective units to be heat-dissipated (cooled) of the noise filter 1 are disposed, and are thermally connected to the first principal face. Specifically, the first principal face of the cooling plate 103 is fixed in a heat exchangeable manner to the respective units to be heat-dissipated (cooled) of the noise filter 1. Furthermore, a second principal face serving as the principal face (the X-Y plane) on a lower face side (the −Z side) of the cooling plate 103 is a heat dissipation face of the noise filter 1. This second principal face is disposed to face a cooling surface of a housing of the power conversion apparatus, and is thermally connected to the cooling surface. Stated another way, the cooling plate 103 of the noise filter 1 according to the present disclosure transports heat from the respective units to be heat-dissipated of the noise filter 1 that are thermally connected to the first principal face of the cooling plate 103 directly or via another member to the housing of the power conversion apparatus via the second principal face opposite to the first principal face.

Note that the cooling plate 103 may be integrally formed as a portion of the housing 101, or may be individually formed and fixed. This fixing may be fixing using welding or an adhesive, or may be detachable fixing using screwing or the like.

Note that side plates (a Y-Z plane and a Z-X plane) of the housing 101 that extend from outer edges of the cooling plate 103 of the noise filter 1 toward the +Z side may be omitted. In this case, the housing of the power conversion apparatus that is mounted with the noise filter 1 may also be used as the side plates of the housing 101. Similarly, an upper face plate (not illustrated) that forms the upper face of the housing 101 of the noise filter 1 may be formed integrally with the side plates as a portion of the housing 101, or may be individually formed to be fixed to the side plates, or the housing of the power conversion apparatus that is mounted with the noise filter 1 may also be used as the upper face plate.

As described above, the noise filter 1 according to the embodiment has a structure in which the periphery is surrounded by the housing 101 that is formed of a metal material. This configuration enables the housing 101 to function as a case that is used for shielding against electromagnetic noise from the outside and heat dissipation from a heat generating component (an electronic component) such as a coil 5, as described later.

AC power that has been supplied from an external single-phase or three-phase AC power supply is input to the noise filter 1 via a plurality of power supply lines. Furthermore, the noise filter 1 outputs AC power after noise removal via the plurality of power supply lines. FIGS. 1 to 3 illustrate, as the plurality of power supply lines, a voltage line L1 through which a single-phase current from the single-phase AC power supply or, for example, a U-phase (first-phase) current from the three-phase AC power supply flows, two voltage lines L2 and L3 that are not electrically connected to the single-phase AC power supply and through which, for example, a V-phase (second-phase) current and a W-phase (third-phase) current from the three-phase AC power supply respectively flow, and a neutral line N that is electrically connected to the single-phase or three-phase AC power supply. Furthermore, the neutral line N is electrically connected to a ground potential via a ground wire G.

As illustrated in FIGS. 1 to 3, the noise filter 1 includes a plurality of Y capacitors 3, a plurality of X capacitors 4, a plurality of coils 5, a plurality of heat dissipation plates 6, and at least one circuit board 7. FIGS. 1 to 3 illustrate two coils 5a and 5b as the plurality of coils 5.

The Y capacitors 3 are line-ground capacitors that are provided between each of the power supply lines, the plurality of voltage lines L1 to L3 of the power conversion apparatus that respectively corresponds to a plurality of phases and the neutral line N, and the ground wire G (between lines). The Y capacitors 3 attenuate common mode noise. In the examples of FIGS. 1 to 3, the plurality of Y capacitors 3 is provided between each of the power supply lines and the ground wire G that is grounded in each of a pre-stage of the coil 5a, a portion between the coils 5a and 5b, and a post-stage of the coil 5b. Note that the noise filter 1 may be configured as an active noise filter. In this case, for example, the Y capacitors 3 that are provided between the coils 5a and 5b are electrically connected to a control circuit (not illustrated) such as a control integrated circuit (IC). For example, the control IC is configured to detect high-frequency noise of each of the power supply lines by using the Y capacitors 3 between the coils 5a and 5b, and cause a current having a magnitude that corresponds to the detected high-frequency noise to flow through each of the power supply lines.

The X capacitors 4 are inter-line capacitors that are provided between each of the voltage lines L1 to L3 and the neutral line N (between lines). The X capacitors 4 primarily attenuate common mode noise. In the examples of FIGS. 1 to 3, the plurality of X capacitors 4 is provided between each of the voltage lines L1 to L3 and the neutral line N in each of the pre-stage of the coil 5a, the portion between the coils 5a and 5b, and the post-stage of the coil 5b.

The coil 5 is, for example, a common mode choke coil or a normal mode choke coil. As an example, the coil 5 is a three-phase four-wire type common mode choke coil that is constituted by four windings. The coil 5 is formed by winding, in phase, windings such as copper wire around a core using a magnetic material. As an example, the coil 5 is a toroidal coil in which windings are disposed around a toroidal type core. Note that the core of the coil 5 is not limited to the toroidal type core, and a core having an arbitrary shape, such as a UU core or a UI core, can be appropriately used.

As an example, the coil 5 is formed in a shape that is annular (hereinafter referred to as an annular shape, or simply referred to as an annulus), such as a toric shape or a hollow rectangular shape. For example, the core of the coil 5 is formed or disposed in an annulus such as a toric shape or a hollow rectangular shape. Stated another way, the core of the coil 5 may be formed by a single core that is formed in an annular shape, or may be formed in an annular shape by assembling (coupling) a plurality of cores.

Note that in the present disclosure, it is assumed that an axis direction of the coil 5 is a direction along a direction in which a central axis or an inner circumference of the annular shape extends. Here, it is assumed that the inner circumference of the annular shape is a hollow portion of the annular shape or the vicinity of the hollow portion. Stated another way, the axis direction of the coil 5 is a direction in which a columnar shape specified by the hollow portion of the annular shape extends. For example, in the states illustrated in FIGS. 1 to 3, the axis direction of the coil 5 is a direction that extends along the cooling plate 103, and runs along an X axis, and is a direction along a stream of disposition of mounted components (electronic components) of the noise filter 1. Furthermore, in the present disclosure, it is assumed that a radial direction of the coil 5 is a direction that is orthogonal to the axis direction, and is a direction from the inner circumference toward an outer circumference in the annular shape.

A pair of leads that are electrically connected to any of the respective voltage lines L1 to L3 and the neutral line N extend from both ends of each of the plurality of windings of the coil 5. In the present disclosure, for example, with respect to the plurality of power supply lines (the voltage lines L1 to L3 and the neutral line N), a “winding start” of a winding refers to an input-side lead in each phase. Similarly, for example, a “winding end” of the winding refers to an output-side lead in each of the phases.

Note that the coil 5 may be a three-phase three- wire type coil that is constituted by three windings that are respectively electrically connected to the voltage lines L1 to L3. A single coil 5 has a filter function of three phases, and this can reduce a cost in comparison with a case where three single-phase type coils are used.

The coil 5 is thermally connected to the cooling plate 103 of the noise filter 1. Furthermore, the coil 5 is held by a holding member (not illustrated) such as a resin mold, and a position and an orientation of the coil 5 are specified.

As illustrated in FIGS. 1 to 3, winding starts and winding ends of all of the windings for the plurality of power supply lines (the voltage lines L1 to L3 and the neutral line N) are located in positions that are different from each other in a circumferential direction around the axis direction of the annular shape of the coil 5. Stated another way, a position of a lead of the coil 5 in the circumferential direction changes among the plurality of phases, and also changes between an input side and an output side.

For example, as illustrated in FIGS. 1 to 3, with regard to each of the plurality of power supply lines (the voltage lines L1 to 13 and the neutral line N), the winding start and the winding end of the winding are located in the same position in the radial direction of the annular shape of the coil 5, and are disposed to be aligned concentrically. Specifically, with respect to each of the plurality of power supply lines, the winding start and the winding end of the winding are aligned to either an outer circumferential side or an inner circumferential side of an annular core. Stated another way, in a pair of an input-side lead and an output-side lead, positions in the radial direction that is orthogonal to the axis direction (the X direction) of the annular shape of the coil 5 (positions on the Y-Z plane) are aligned to either the inner circumferential side or the outer circumferential side of the annular shape for each phase of the plurality of phases. Note that, in an arbitrary phase of the plurality of phases, the input-side and output-side leads may be located in different positions in the radial direction of the annular shape of the coil 5, that is, different positions of the inner circumferential side and the outer circumferential side. In other words, in some phases (at least one phase) of the plurality of phases, the input-side and output-side leads of the coil 5 may be located in positions different from each other of the inner circumferential side and the outer circumferential side of the annular shape, and in each of the other phases, the input-side and output-side leads may be located to be aligned to either the inner circumferential side or the outer circumferential side. Whether the input-side and output-side leads will be located in different positions in the radial direction in an arbitrary phase or which phase the input-side and output-side leads will be located in different positions in can be appropriately determined on the basis of dispositions of mounted components including the coil 5, the routing of wiring, or the like. Stated another way, in an arbitrary phase, the input-side and output-side leads are located in different positions in the radial direction, and this can further improve a degree of freedom of the mounted components or the routing of wiring.

On the other hand, as illustrated in FIGS. 1 to 3, with regard to each of the plurality of power supply lines (the voltage lines L1 to L3 and the neutral line N), the winding start and the winding end of the winding are located in positions that are opposite to each other in the axis direction of the core of the annular shape (the coil 5). Specifically, a plurality of power supply lines of an input side that is electrically connected to one of the winding start and the winding end of the winding is provided opposite to a plurality of power supply lines on an output side that is electrically connected to another in the axis direction of the coil 5. Stated another way, in each of the plurality of phases, the input-side lead and the output-side lead that extend from the winding of the coil 5 extend opposite to each other in the axis direction of the annular shape of the coil 5.

As illustrated in FIGS. 1 to 3, the coil 5 is disposed on the first principal face of the cooling plate 103 in a state where the coil 5 is perpendicular to the principal face (the X-Y plane) of the cooling plate 103. In other words, the coil 5 is disposed on the first principal face of the cooling plate 103 in an orientation that reduces an area of projection onto the principal face of the cooling plate 103. Specifically, as illustrated in FIGS. 1 to 3, the coil 5 is disposed on the cooling plate 103 of the noise filter 1 in such a way that the axis direction of the coil 5 matches a direction (the X direction) along a stream of disposition of mounted components (electronic components) of the noise filter 1. In other words, with respect to the coil 5 that is disposed on the cooling plate 103 of the noise filter 1, the winding start and the winding end of each of the windings are provided opposite to each other in the direction (the X direction) along the stream of disposition of the electronic components in the noise filter 1.

Accordingly, as illustrated as alternating long and two short dashed line P1 in FIGS. 2 and 3, in the noise filter 1 according to the present disclosure, with respect to the coil 5 that is disposed on the cooling plate 103 of the noise filter 1, the winding starts of the plurality of windings in the plurality of phases are located in the same position in the direction (the X direction) along the stream of disposition of the electronic components. Stated another way, in all of the plurality of phases, the input-side lead of the coil 5 is located in the same position in the axis direction (the X direction) of the annular shape.

Similarly, as illustrated as alternating long and two short dashed line P2 in FIGS. 2 and 3, in the noise filter 1 according to the present disclosure, with respect to the coil 5 that is disposed on the cooling plate 103 of the noise filter 1, the winding ends of the plurality of windings in the plurality of phases are located in the same position in the direction along the stream of disposition of the electronic components. Stated another way, in all of the plurality of phases, the output-side lead of the coil 5 is located in the same position in the axis direction (the X direction) of the annular shape.

Furthermore, as illustrated in FIGS. 1 to 3, the plurality of power supply lines (the voltage lines L1 to L3 and the neutral line N) that is electrically connected to the coil 5 extends from each of the winding starts and the winding ends of the respective windings in the direction along the stream of disposition of the electronic components in the noise filter 1.

As described above, the coil 5 of the noise filter 1 according to the present embodiment is configured to draw out both ends of the winding opposite to each other in the axis direction. In this coil 5, a position in the radial direction of the winding start around the core is similar to a position in a coil that is configured to draw out both ends of the winding toward the same side in the axis direction, and it is sufficient if only a position of the winding end is changed, and stated another way, it is sufficient if the number of times of winding is changed by half of the circumference of the core. Therefore, the ease of manufacturing can be maintained.

The heat dissipation plate 6 is a member that is formed in a flat plate shape. The heat dissipation plate 6 is formed by using a metal material having thermal conductivity, such as die casting or aluminum. It is sufficient if the type of the metal material or the thickness (a length in the X direction) of the heat dissipation plate 6 is appropriately selected according to, for example, an amount of heat dissipation from the coil 5 and a distance from the coil 5. Note that the heat dissipation plate 6 is not an essential component, and is omitted from the noise filter 1 in some cases. In a case where heat can be appropriately dissipated from the coil 5, for example, in a case where the housing 101 is filled with a heat dissipation cushioning material such as a potting material or in a case where packaging density in the housing 101 is small, the heat dissipation plate 6 may be omitted from the noise filter 1.

As illustrated in FIGS. 1 to 3, a plurality of heat dissipation plates 6 is provided at both sides of each of the coils 5a and 5b in the direction (the X direction) along the stream of disposition of the electronic components. Furthermore, the heat dissipation plates 6 are disposed on the cooling plate 103 of the noise filter 1, and are thermally connected to the cooling plate 103. The heat dissipation plates 6 transport heat from the coil 5 to the cooling plate 103, and dissipate heat. In the heat dissipation plates 6, the principal face (the Y-Z plane) extends in a direction away from the cooling plate 103. This direction away from the cooling plate 103 is, for example, a direction (the Z direction) that is orthogonal to the cooling plate 103.

Note that the heat dissipation plate 6 may only be disposed at any one side of each of the coils 5a and 5b in the direction (the X direction) along the stream of disposition of the electronic components. Stated another way, a plane (the Y-Z plane) that is orthogonal to the axis direction (the X direction) of the annular shape of the coil 5 faces each principal face of at least one heat dissipation plate 6. For example, the coil 5 is disposed between respective principal faces of a pair of heat dissipation plates 6 in the axis direction (the X direction) of the annular shape.

Note that in the heat dissipation plate 6, the principal face may have an inclination relative to the Y-Z plane. Stated another way, the heat dissipation plate 6 is orthogonal to, for example, the cooling plate 103 of the noise filter 1, but can be appropriately tilted relative to the cooling plate 103 in accordance with, for example, limitations in a height direction (the Z direction) or the layout of respective components.

Note that the cooling plate 103 of the noise filter 1 and the plurality of heat dissipation plates 6 may be integrally formed, or may be individually formed and fixed. This fixing may be fixing using welding or an adhesive, or may be detachable fixing using screwing or the like.

As described above, by employing a configuration in which the coil 5 is disposed to be perpendicular to the principal face of the cooling plate 103, an electric flow in the noise filter 1 can be made to match the stream of disposition (terminal arrangement) of the electronic components. Accordingly, the configuration described above can reduce unnecessary drawing around of power supply lines (wiring lines) among the electronic components, and can achieve a reduction in size of the noise filter 1.

Furthermore, by employing a configuration in which, in all of the plurality of phases, the input side and the output side are provided to be opposite to each other in the direction along the stream of disposition of the electronic components, even in a case where a plural-wire type coil 5 including three or more windings is used, an input-side wiring line (a power supply line) does not cross an output-side wiring line, and wiring lines of respective phases do not cross each other. This can reduce a probability of a deterioration in filter performance due to capacity coupling in a crossing portion.

Furthermore, in the noise filter 1, the X capacitors 4 and the Y capacitors 3 before and after the coil 5 can be disposed to be neatly aligned along the electric flow, and this can reduce a dead space caused by the drawing around of a wiring line.

As illustrated in FIGS. 1 to 3, the heat dissipation plate 6 is shorter than a width (a length in the Y-direction) of the housing 101 of the noise filter 1. Here, the width of the housing 101 of the noise filter 1 is a length in a direction that is orthogonal to the axis direction (the X direction) of the annular shape of the coil 5, and runs along the first principal face of the cooling plate 103. In this width direction of the housing 101, a clearance 105 is formed between at least one heat dissipation plate 6 and the side plate of the housing 101 of the noise filter 1. Note that the clearance 105 may be omitted.

As an example, from among the plurality of power supply lines (a plurality of wiring lines) of the plurality of phases, the voltage lines L1 to L3 are drawn around above the heat dissipation plate 6 (on the +Z side). For example, in a power conversion apparatus that is configured to be operable according to an input of each of single-phase and three-phase AC power supplies by using a three-phase four-wire type coil 5, in a case where three-phase AC power is input, a current of an N-phase is canceled by a phase difference among respective phases. In contrast, in a case where single-phase AC power is input, a large current flows in the N-phase, and this increases loss in comparison with another L-phase. Therefore, from among four wiring lines that are connected to the three-phase four-wire type coil 5, a neutral line N of the N-phase has an amount of heat generation that is larger than an amount of the voltage lines L1 to L3 of the other L-phase. Therefore, as an example, in the case of the three-phase four-wire type, the neutral line N passes through the clearance 105 between the housing 101 of the noise filter 1 and the heat dissipation plate 6, and is drawn around near the cooling plate 103. Note that in addition to or instead of the N-phase, power supply lines of another phase may be drawn around through the clearance 105. Stated another way, from among the plurality of power supply lines (the voltage lines L1 to L3 and the neutral line N) of the plurality of phases, at least a power supply line (a wiring line) that corresponds to one phase is drawn around on the cooling plate 103 side inside the housing 101, and passes through the clearance 105.

The circuit board 7 is electrically connected, for example, to each of the plurality of power supply lines of the plurality of phases, and the plurality of Y capacitors 3 and the plurality of X capacitors 4 that are provided between the coils 5a and 5b, and has a wiring pattern that includes a wiring line that electrically connects lines, or a line and a ground. For example, in the noise filter 1 configured as an active noise filter, on the circuit board 7, a control IC that is configured to detect high-frequency noise by using the Y capacitors 3 provided between the coils 5a and 5b and cause a noise canceling current that corresponds to the detected high-frequency noise to flow through respective power supply lines, and its peripheral circuit may be mounted. Note that, for example, in a case where all connections between a power supply line and a component are direct joining using welding or the like, the circuit board 7 can be omitted in some cases.

Furthermore, in the noise filter 1 according to the present embodiment, a space between at least one heat dissipation plate 6 and the coil 5 may be filled with a heat dissipation cushioning material, such as a filler or a potting material, that has at least heat dissipation (thermal conductivity) and electric insulation. Stated another way, in the noise filter 1, a space between a pair of heat dissipation plates 6 that face each other with at least the coil 5 interposed therebetween may be filled with the heat dissipation cushioning material. Stated another way, the heat dissipation cushioning material may be used as a heat dissipation route from the coil 5. Note that in a case where insulation treatment has been performed on respective components, such as the coil 5, that are disposed in the housing 101 of the noise filter 1 or in a case where a sufficient distance of insulation can be secured, the heat dissipation cushioning material may not have electric insulation. Furthermore, the entirety of an inside of the housing 101 of the noise filter 1 may be filled with the heat dissipation cushioning material.

As described above, by employing a configuration in which a space around the coil 5 is filled with the heat dissipation cushioning material, a distance of insulation between the coil 5 and a peripheral component can be secured and reduced to a minimum physical length. Furthermore, the employed heat dissipation cushioning material can hold components, such as the coil 5, of the noise filter 1, and therefore countermeasures can be taken against vibration of the noise filter 1 while reducing the number of structures for countermeasures against vibration, such as a support member or a fixing member including a mold or the like.

As illustrated in FIGS. 1 to 3, electric connection between components in the noise filter 1, such as connection among the coils 5a and 5b, the Y capacitors 3, and the X capacitors 4, can be achieved by performing welding or the like to directly join leads of mounted components (electronic components) without a circuit board interposed therebetween. This configuration can prevent the number of structures from increasing according to an increase in the number of connection portions, for example, by disposing a fixing member such as a screw or disposing a bus bar for relaying electric connection. This can reduce the number of circuit boards, or can reduce a circuit board to be mounted in size.

Note that the power conversion apparatus according to the present disclosure includes a pre-stage or post-stage circuit configuration of the noise filter 1, such as an AC connector, a fuse, a varistor, or a phase switching relay. Electric connection between the circuit configuration described above and the noise filter 1 or between circuit configurations may also be achieved by performing welding or the like to directly join leads of mounted components without the circuit board interposed therebetween. This configuration can achieve a reduction in size of the entirety of the power conversion apparatus mounted with the noise filter 1.

Furthermore, the noise filter 1 according to the embodiment may be disposed in the housing 101 together with the pre-stage or post-stage circuit configuration of the noise filter 1, such as the AC connector, the fuse, the varistor, or the phase switching relay, and may be formed integrally as a noise filter module. For example, the circuit board 7 may be mounted with a control circuit of a phase switching relay (not illustrated) or a rush prevention circuit relay (not illustrated). As an example, the control circuit of the phase switching relay controls an operation of the phase switching relay, and switches a phase of AC power supplied to each of the plurality of voltage lines L1 to L3 between a phase that corresponds to each of the voltage lines and a single phase that is common to the plurality of voltage lines L1 to L3. As an example, the control circuit of the rush prevention circuit relay controls an operation of the rush prevention circuit relay that is provided in parallel to a rush current prevention element, such as a temperature fuse resistor, a cement resistor, or a thermistor, in a rush prevention circuit, and prevents a rush current from flowing into a power factor correction circuit (not illustrated) in a post-stage of the noise filter 1. This configuration can reduce a cost of manufacturing the power conversion apparatus.

Furthermore, in the power conversion apparatus according to the present disclosure, a plurality of noise filters 1 may be mounted in series or in parallel to be extensible. Stated another way, the power conversion apparatus according to the present disclosure may have extensibility by disposing and modularizing a plurality of components in the housing 101. By employing a configuration in which the plurality of noise filters 1 is mounted in series or in parallel, noise can be further prevented from entering the power conversion apparatus or flowing out to the outside.

Note that some components in the noise filter 1 may be electrically connected via a circuit board such as the circuit board 7, or a junction holder that includes a bus bar for relaying electric connection, and a resin hold that holds the bus bar or a mounted component may be disposed above the housing 101 (on the +Z side), and electric connection may be achieved.

### Comparative Example

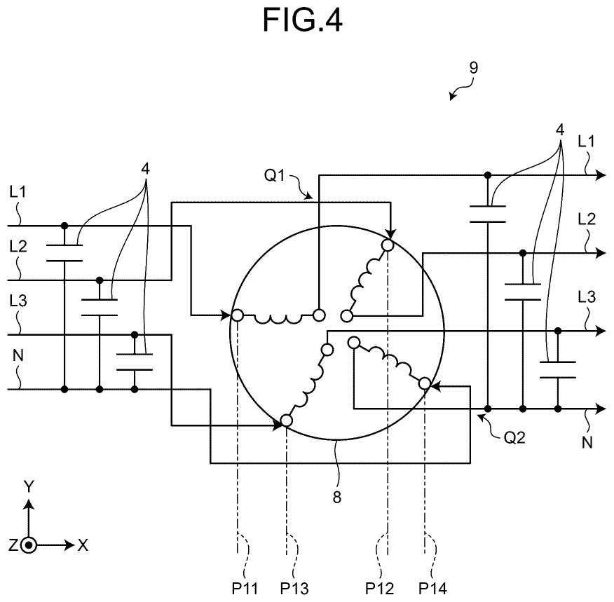

FIG. 4 is a diagram schematically illustrating an example of a configuration of a noise filter 9 in a comparative example. FIG. 4 schematically illustrates a configuration of the noise filter 9 in the comparative example when viewed from an upper face side (the +Z side).

As illustrated as the noise filter 9 in the comparative example, in order to cool down a coil 8 such as a common mode choke coil, the coil 8 that is formed in an annulus is horizontally disposed in such a way that a heat dissipation face (a face on the −Z side) of the coil 8 is parallel to a cooling surface of a housing, and an axis direction is orthogonal to the cooling surface of the housing in many cases. In a case where the coil 8 is horizontally disposed, a circuit board (not illustrated) that electrically connects the coil (an electronic component) and its pre-stage and post-stage mounted components (electronic components) is disposed in parallel to a heat dissipation face of the coil 8, for example, along a stream of disposition of the respective electronic components in some cases.

For example, in a single-phase coil, wiring lines are simply drawn out from the coil, and the layout of peripheral electronic components is simple, even in a case where the coil is horizontally disposed.

Under the circumstances, as illustrated in FIG. 4, in the case of a toroidal coil 8 of a plural-phase plural-wire type, for example, for the sake of ease of manufacturing, in all of a plurality of windings of a plurality of phases, a winding start around a core is disposed on an outer circumferential side, a winding end is disposed on an inner circumferential side, and the winding start and the winding end are drawn out to the same side (for example, the +Z side) in the axis direction (the Z direction). Therefore, as illustrated in FIG. 4, in a case where a plural-wire type coil 8 including three or more windings, such as a three-phase four-wire type toroidal common mode choke coil, is horizontally disposed, a structure of the windings is complicated, for example, in such a way that with respect to a plurality of power supply lines (wiring lines) that is respectively connected to a plurality of windings, wiring lines of any phases cross each other, and there is a need for a space for drawing around. Furthermore, for example, the disposition of the X capacitors 4 that are disposed before and after the coil 8 is also complicated, and there is a further need for a space for drawing around the wiring lines in some cases.

In general, it has been requested that power conversion apparatuses such as chargers mounted in electric vehicles or the like be reduced in size due to, for example, limitations on a mounting space. Therefore, the noise filters including the plural-phase plural-wire type coil have room for improvements from the viewpoint of, for example, a reduction in size.

Furthermore, for example, a configuration using a square coil 8 reduces complication of drawing around wiring lines, but there has been a problem of an increase in a cost.

For example, as illustrated in FIG. 4, positions P11, P12, P13, and P14 of winding starts of windings are different from each other in a direction (the X direction) along a stream of disposition of electronic components. Therefore, on each of an input side and an output side of the coil 8, there is a need for a space for drawing around the wiring lines.

Furthermore, for example, as illustrated in FIG. 4, in a case where a plural-wire type common mode coil including three or more windings is horizontally disposed, there are crossing portions, such as a crossing portion Q1 where an input-side voltage line L2 and an output-side voltage line L1 cross each other or a crossing portion Q2 where input-side and output-side neutral lines N cross each other, in some cases. In a crossing portion of an input-side wiring line (a power supply line) and an output-side wiring line, or a crossing portion of wiring lines of phases, there is a possibility of a deterioration in filter performance due to capacity coupling.

In contrast to the noise filter 9 in the comparative example described above, the noise filter 1 according to the present disclosure includes the coil 5 of a plural-phase plural-wire type that is vertically disposed on a horizontal cooling surface (the first principal face of the cooling plate 103), and the input-side lead and the output-side lead of the coil 5 are drawn out opposite to each other in the axis direction (the X direction) of the coil 5.

By employing a configuration according to the present disclosure in which the coil 5 is disposed to be perpendicular to the principal face of the cooling plate 103, an electric flow in the noise filter 1 can be made to match the stream of disposition (terminal arrangement) of the electronic components. Accordingly, the configuration according to the present disclosure can reduce unnecessary drawing around of power supply lines (wiring lines) among the electronic components, and can achieve a reduction in size of the noise filter 1.

Furthermore, by employing a configuration according to the present disclosure in which, in all of the plurality of phases, the input side and the output side are provided to be opposite to each other in the direction along the stream of disposition of the electronic components, even in a case where a plural-wire type common mode coil including three or more windings is used, an input-side wiring line (a power supply line) does not cross an output-side wiring line, and wiring lines of respective phases do not cross each other. This can reduce a probability of a deterioration in filter performance due to capacity coupling in a crossing portion.

According to at least one embodiment described above, a noise filter including a plural-phase plural-wire type coil can be reduced in size.

According to the present disclosure, the noise filter including the plural-phase plural-wire type coil can be reduced in size. Note that the advantageous effect described here is not necessarily restrictive, and any of the advantageous effects described herein may be exhibited.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### Supplementary Notes

The description of the embodiments described above discloses the technique described below.

### 1

A noise filter including:
a cooling plate that has thermal conductivity, and is formed in a flat plate shape;
a coil of a type of a plurality of wires of a plurality of phases, the coil being formed in an annular shape, and being fixed to a first principal face of the cooling plate;
a plurality of wiring lines that are electrically connected to leads that extend from windings of the plurality of phases; and
a plurality of capacitors that are electrically connected to the plurality of wiring lines, in which
the coil is thermally connected to the first principal face of the cooling plate, and an axis direction of the annular shape extends along the first principal face, in a state where the coil is fixed to the first principal face.

### 2

The noise filter according to (1), in which in each of the plurality of phases, an input-side lead and an output-side lead extend opposite to each other in the axis direction of the annular shape, the input-side lead and the output-side lead extending from each of the windings of the coil.

### 3

The noise filter according to (1) or (2), in which
a position of the input-side lead in the axis direction of the annular shape is the same in all of the plurality of phases, and
a position in the axis direction of the output-side lead is the same in all of the plurality of phases.

### 4

The noise filter according to any one of (1) to (3), in which
a position of the input-side lead in a radial direction and a position of the output-side lead in the radial direction are aligned to any one of an inner circumferential side and an outer circumferential side of the annular shape in each phase of the plurality of phases, the radial direction being orthogonal to the axis direction of the annular shape.

### 5

The noise filter according to any one of (1) to (3), in which
a position of the input-side lead in a radial direction and a position of the output-side lead in the radial direction are:
different from each other between an inner circumferential side and an outer circumferential side of the annular shape in some phases of the plurality of phases; and
aligned to any one of the inner circumferential side and the outer circumferential side in a remaining phase of the plurality of phases, the radial direction being orthogonal to the axis direction of the annular shape.

### 6

The noise filter according to any one of (1) to (5), in which
positions of the leads in a circumferential direction around the axis direction of the annular shape are different among the plurality of phases, and different between the input side and the output side.

### 7

The noise filter according to any one of (1) to (6), further including
at least one heat dissipation plate that has thermal conductivity, and is formed in the flat plate shape, in which
a face that is orthogonal to the axis direction of the annular shape of the coil faces each principal face of the at least one heat dissipation plate.

### 8

The noise filter according to (7), further including
a side plate that extends from an outer edge of the cooling plate toward the first principal face, in which
the cooling plate and the side plate form a housing of the noise filter,
a clearance is formed between the at least one heat dissipation plate and the side plate in a direction that is along the first principal face and orthogonal to the axis direction of the annular shape of the coil, and
a wiring line that corresponds to at least one phase of the plurality of phases from among the plurality of wiring lines is drawn around closer to the cooling plate inside the housing of the noise filter, and passes through the clearance.

### 9

The noise filter according to (7) or (8), in which
a heat dissipation cushioning material having at least thermal conductivity fills between the coil and the at least one heat dissipation plate.

### 10

The noise filter according to any one of (1) to (9), in which
the coil is a toroidal coil.

### 11

A power conversion apparatus including:
the noise filter according to any one of (1) to (10); and
a housing in which a flow passage of coolant that runs in one surface is formed, in which
the noise filter is detachably fixed to the housing, and
in a state where the noise filter is fixed to the housing, a second principal face of the cooling plate of the noise filter opposite to the first principal face is thermally connected to the housing.

### 12

A power conversion apparatus including:
the noise filter according to any one of (1) to (10) described above; and
a power conversion circuit that is disposed in a post-stage of the noise filter, converts, into direct current power, alternating current power supplied from an external single-phase or three-phase alternating current power supply via the noise filter, and outputs the direct current power that has been converted.

### 13

A vehicle including:
the power conversion apparatus according to (11) or (12) described above; and
a battery that is charged by using direct current power that has been converted by the power conversion apparatus.

What is claimed is:

1. A noise filter comprising:
a cooling plate that has thermal conductivity, and is formed in a flat plate shape;
a coil of a type of a plurality of wires of a plurality of phases, the coil being formed in an annular shape, and being fixed to a first principal face of the cooling plate;
a plurality of wiring lines that are electrically connected to leads that extend from windings of the plurality of phases; and
a plurality of capacitors that are electrically connected to the plurality of wiring lines, wherein
the coil is thermally connected to the first principal face of the cooling plate, and an axis direction of the annular shape extends along the first principal face, in a state where the coil is fixed to the first principal face.

2. The noise filter according to claim 1, wherein
in each of the plurality of phases, an input-side lead and an output-side lead extend opposite to each other in the axis direction of the annular shape, the input-side lead and the output-side lead extending from each of the windings of the coil.

3. The noise filter according to claim 2, wherein
a position of the input-side lead in the axis direction of the annular shape is the same in all of the plurality of phases, and
a position in the axis direction of the output-side lead is the same in all of the plurality of phases.

4. The noise filter according to claim 2, wherein
a position of the input-side lead in a radial direction and a position of the output-side lead in the radial direction are aligned to any one of an inner circumferential side and an outer circumferential side of the annular shape in each phase of the plurality of phases, the radial direction being orthogonal to the axis direction of the annular shape.

5. The noise filter according to claim 2, wherein
a position of the input-side lead in a radial direction and a position of the output-side lead in the radial direction are:
different from each other between an inner circumferential side and an outer circumferential side of the annular shape in some phases of the plurality of phases; and
aligned to any one of the inner circumferential side and the outer circumferential side in a remaining phase of the plurality of phases, the radial direction being orthogonal to the axis direction of the annular shape.

6. The noise filter according to claim 2, wherein
positions of the leads in a circumferential direction around the axis direction of the annular shape are different among the plurality of phases, and different between the input side and the output side.

7. The noise filter according to claim 1, further comprising
at least one heat dissipation plate that has thermal conductivity, and is formed in the flat plate shape, wherein
a face that is orthogonal to the axis direction of the annular shape of the coil faces each principal face of the at least one heat dissipation plate.

8. The noise filter according to claim 7, further comprising
a side plate that extends from an outer edge of the cooling plate toward the first principal face, wherein
the cooling plate and the side plate form a housing of the noise filter,
a clearance is formed between the at least one heat dissipation plate and the side plate in a direction that is along the first principal face and orthogonal to the axis direction of the annular shape of the coil, and
a wiring line that corresponds to at least one phase of the plurality of phases from among the plurality of wiring lines is drawn around closer to the cooling plate inside the housing of the noise filter, and passes through the clearance.

9. The noise filter according to claim 7, wherein
a heat dissipation cushioning material having at least thermal conductivity fills between the coil and the at least one heat dissipation plate.

10. The noise filter according to claim 1, wherein
the coil is a toroidal coil.

11. A power conversion apparatus comprising:
the noise filter according to claim 1; and
a housing in which a flow passage of coolant that runs in one surface is formed, wherein
the noise filter is detachably fixed to the housing, and
in a state where the noise filter is fixed to the housing, a second principal face of the cooling plate of the noise filter opposite to the first principal face is thermally connected to the housing.
